(19) United States
(12) Patent Application Publication
(10) Pub. No.: US 2024/0402424 A1
(43) Pub. Date: Dec. 5, 2024

(54) OPTICAL CIRCUIT BOARD AND OPTICAL COMPONENT MOUNTING STRUCTURE USING SAME

(71) Applicant: KYOCERA Corporation, Kyoto-shi, Kyoto (JP)

(72) Inventor: Yoshinori NAKATOMI, Nagahama-shi (JP)

(73) Assignee: KYOCERA Corporation, Kyoto-shi, Kyoto (JP)

(21) Appl. No.: 18/690,899

(22) PCT Filed: Sep. 12, 2022
(86) PCT No.: PCT/JP2022/033987

§ 371 Date: Mar. 11, 2024

(30) Foreign Application Priority Data
Sep. 13, 2021 (JP) 2021-148694

(51) Int. Cl. G02B 6/122; G02B 6/12; H01L 25/16

(52) U.S. Cl. CPC G02B 6/1228; G02B 2006/12061; H01L 25/167

(57) ABSTRACT

An optical circuit includes a wiring board and an optical waveguide. Part of an upper surface of the wiring board is a mounting region of an optical component. The optical waveguide is positioned adjacent to the mounting region of the optical component on the wiring board, and includes a core, a first cladding, and a second cladding. The core includes a first portion and a second portion. The first cladding is positioned sandwiching upper and lower surfaces of the first portion of the core, and the second cladding is positioned sandwiching upper and lower surfaces of the second portion of the core. The width of the second portion is greater than the width of the first portion, and the thickness of the second portion is greater than the thickness of the first portion. The refractive index of the second cladding is greater than the refractive index of the first cladding.

### TECHNICAL FIELD

The present invention relates to an optical circuit board and an optical component mounting structure using the same.

### BACKGROUND OF INVENTION

In recent years, optical fiber that can communicate large amounts of data at high speed has been used for information communication (e.g., Patent Document 1). Optical signals are transmitted and received between the optical fiber and an optical element (silicon photonics device).

### CITATION LIST

### Patent Literature

Patent Document 1: JP 2009-288614 A

### SUMMARY

### Solution to Problem

An optical circuit board according to the present disclosure includes a wiring board including an upper surface and an optical waveguide. A part of the upper surface of the wiring board is a mounting region of an optical component. The optical waveguide is positioned adjacent to the mounting region of the optical component on the wiring board, and includes a core, a first cladding, and a second cladding. The core includes a first portion having a first upper surface and a first lower surface and a second portion having a second upper surface and a second lower surface. The first cladding is positioned sandwiching the first upper surface and the first lower surface of the first portion of the core, and the second cladding is positioned sandwiching the second upper surface and the second lower surface of the second portion of the core. The width of the second portion is greater than the width of the first portion, and the thickness of the second portion is greater than the thickness of the first portion. The refractive index of the second cladding is greater than the refractive index of the first cladding.

According to the present disclosure, an optical component mounting structure includes the optical circuit board described above and the optical component mounted in the mounting region.

### BRIEF DESCRIPTION OF THE DRAWINGS

FIG. 1 is a plan view illustrating an optical component mounting structure in which a silicon photonics device and an electronic component are mounted on an optical circuit board according to an embodiment of the present disclosure.

FIG. 2 is an enlarged explanatory view for describing a cross section, taken in the longitudinal direction, of a region X illustrated in FIG. 1.

FIG. 3 is an enlarged explanatory view for describing a cross-section shape of a core in a region Y illustrated in FIG. 2, when a cross section is taken in an extending direction of the core.

FIG. 4 is an enlarged explanatory view for describing a planar shape of the core in the region Y illustrated in FIG. 2.

FIG. 5 is an explanatory view for describing a positional relationship between a first cladding and a second cladding, when a cross section is taken in the extending direction of the core.

FIG. 6 is an explanatory view for describing a positional relationship between the first cladding and the second cladding, when a cross section is taken in the extending direction of the core.

FIG. 7 is an explanatory view for describing a positional relationship between the first cladding and the second cladding, when a cross section is taken in the extending direction of the core.

FIG. 8 is an explanatory view for describing a positional relationship between the first cladding and the second cladding, when a cross section is taken in the extending direction of the core.

### DESCRIPTION OF EMBODIMENTS

When evaluating the connectivity between an optical element, such as a silicon photonics device, and an optical fiber, an index called MFD (mode field diameter) is used. The MFD refers to a diameter of light of a portion having a predetermined intensity or more, of an optical signal passing through the optical element or the optical fiber. Typically, the MFD of the optical element and the MFD of the optical fiber are different from each other, and the larger the difference therebetween, the larger the connection loss. As a result, the signal quality deteriorates. Therefore, there is a demand for an optical circuit board capable of reducing connection loss between the optical element and the optical fiber.

In the optical circuit board according to the present disclosure, as described above, the width of the second portion is greater than the width of the first portion, and the thickness of the second portion is greater than the thickness of the first portion. The refractive index of the second cladding is greater than the refractive index of the first cladding. With such a configuration, according to the optical circuit board of the present disclosure, connection loss between the optical element and the optical fiber can be reduced.

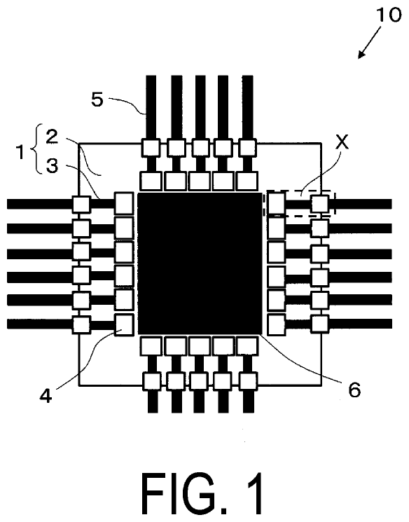

The optical circuit board according to the present disclosure will be described with reference to FIGS. 1 to 4. FIG. 1 is a plan view illustrating an optical component mounting structure 10 in which a silicon photonics device (optical component) 4 is mounted on an optical circuit board 1 according to an embodiment of the present disclosure.

In the embodiment of the present disclosure, the optical circuit board 1 includes a wiring board 2 and an optical waveguide 3. Examples of the wiring board 2 included in the optical circuit board 1 according to the embodiment include a wiring board typically used for an optical circuit board. A part of the upper surface of the wiring board 2 is a mounting region on which the optical component 4 is mounted.

Although not specifically illustrated, the wiring board 2 includes, for example, a core substrate and a build-up layer layered on both surfaces of the core substrate. The core substrate is not particularly limited as long as the core substrate is made of a material having an insulation property. Examples of the material having an insulation property include resins such as an epoxy resin, a bismaleimide-triazine resin, a polyimide resin, and a polyphenylene ether resin. Two or more of these resins may be mixed and used. The core substrate usually includes a through hole conductor for electrically connecting the upper and lower surfaces of the core substrate.

The core substrate may contain a reinforcing material. Examples of the reinforcing material include insulation fabric materials such as glass fiber, glass non-woven fabric, aramid non-woven fabric, aramid fiber, and polyester fiber. Two or more types of reinforcing materials may be used in combination. Inorganic filler made of, for example, silica, barium sulfate, talc, clay, glass, calcium carbonate, titanium oxide, or the like may be dispersed in the core substrate.

The build-up layer has a structure in which insulating layers and conductor layers are alternately layered. A part of the outermost conductor layer (conductor layer positioned on the upper surface of the wiring board) includes a first conductor layer 21a at which the optical waveguide 3 is positioned. The conductor layer is a metal layer made of metal such as copper. The insulating layer included in the build-up layer is not limited to any particular material as long as the insulating layer has the same insulation property as and/or a similar insulation property to the core substrate. Examples of the material having an insulation property include resins such as an epoxy resin, a bismaleimide-triazine resin, a polyimide resin, and a polyphenylene ether resin. Two or more of these resins may be mixed and used.

When two or more insulating layers are present in the build-up layer, the insulating layers may be made of the same resin or may be made of different resins. The insulating layer included in the build-up layer and the core substrate may be made of the same resin or may be made of different resins. The build-up layer usually includes a via hole conductor for electrically connecting the layers.

An inorganic filler made of, for example, silica, barium sulfate, talc, clay, glass, calcium carbonate, or titanium oxide may be dispersed in the insulating layer included in the build-up layer.

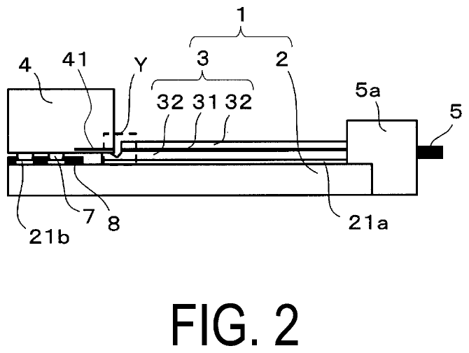

As illustrated in FIG. 2, the optical waveguide 3 included in the optical circuit board 1 according to the embodiment is positioned on a surface of the first conductor layer 21a, which is a surface of the wiring board 2. More specifically, the optical waveguide 3 is positioned adjacent to the silicon photonics device (optical component) 4 on the wiring board 2 (adjacent to the mounting region of the optical component 4 on the wiring board 2). FIG. 2 is an enlarged explanatory view for describing a cross section, taken in the longitudinal direction, of a region X illustrated in FIG. 1. The optical waveguide 3 has a structure in which a cladding 32, a core 31, and a cladding 32 are layered in this order from the first conductor layer 21a side.

The core 31 included in the optical waveguide 3 is a portion through which an optical signal that has entered the optical waveguide 3 propagates. The material forming the core 31 is not limited and is set as appropriate in consideration of, for example, light transmission properties and wavelength characteristics of light propagating therethrough. Examples of the material include an epoxy resin and a silicone resin. The refractive index of the core 31 is greater than the refractive index of the cladding 32, and the optical signal propagates through the core 31 due to such a difference between the refractive indexes.

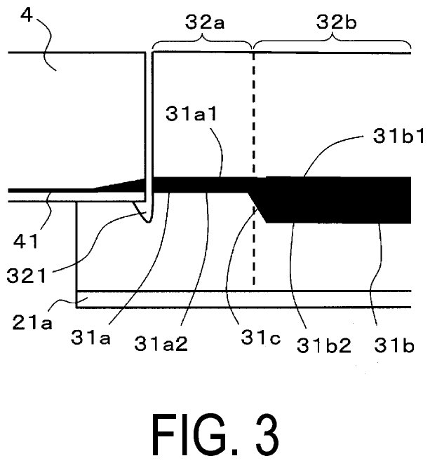

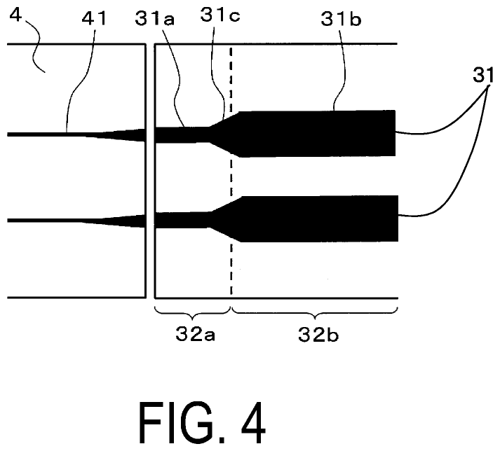

As illustrated in FIGS. 3 and 4, the core 31 is positioned facing a silicon waveguide (Si waveguide) 41 included in the silicon photonics device 4, at one end portion of the optical waveguide 3. That is, the core 31 is positioned such that a side surface of the Si waveguide 41 and a side surface of the core 31 of the optical waveguide 3 face each other. At this end portion, optical signals are transmitted and received between the core 31 and the Si waveguide 41. As illustrated in FIG. 4, a single optical waveguide 3 includes a plurality of the cores 31. FIG. 3 is an enlarged explanatory view for describing a cross-section shape of the core in a region Y illustrated in FIG. 2, when a cross section is taken in an extending direction of the core. FIG. 4 is an enlarged explanatory view for describing a planar shape of the core in the region Y illustrated in FIG. 2.

As illustrated in FIGS. 3 and 4, the core 31 includes a first portion 31a having a first upper surface 31a1 and a first lower surface 31a2, a second portion 31b having a second upper surface 31b1 and a second lower surface 31b2, and a tapered portion 31c. Of the core 31, the first portion 31a is positioned closer to the optical component 4, and the second portion 31b is positioned farther from the optical component 4. The width of the first portion 31a in a plan view and the thickness thereof in a cross-sectional view (hereinafter, simply referred to as “the width and the thickness” in some cases) are set in accordance with the width and the thickness of the Si waveguide 41 included in the silicon photonics device 4, for example. Specifically, the width and the thickness of the first portion 31a are determined such that the MFD (mode field diameter) of the Si waveguide 41 and the MFD of the first portion 31a facing the Si waveguide 41 are caused to be approximate to each other. The determination method will be described below. The length of the first portion 31a is not limited. The width of the first portion 31a is relatively small, and the adhesion force of the first portion 31a with respect to the cladding 32 is small. Thus, for example, from the viewpoint of manufacturing with reduced peeling at the time of exposure and development, which steps of forming the first portion 31a, the thickness of the first portion 31a is preferably 20 μm or more and 500 μm or less.

The width and the thickness of the second portion 31b are greater than the width and the thickness of the first portion 31a. The first portion 31a and the second portion 31b are connected via the tapered portion 31c. An end portion of the tapered portion 31c on the first portion 31a side has substantially the same width and thickness as those of the first portion 31a, and an end portion of the tapered portion 31b on the second portion 31b side has substantially the same width and thickness as those of the second portion 31b. Due to the presence of the tapered portion 31c, the optical signal passing through the core 31 is hardly reflected, and thus loss can be further reduced.

The central axis of the first portion 31a and the central axis of the second portion 31b may be coaxial with each other. When the central axis of the first portion 31a and the central axis of the second portion 31b are coaxial with each other, the transmission efficiency of the optical signal is further improved.

Alternatively, the upper surface of the first portion 31a may be flush with the upper surface of the second portion 31b, and the center of the width of the first portion 31a and the center of the width of the second portion 31b may coincide with each other in a plan view. Even with such a configuration, the transmission efficiency of the optical signal is further improved.

Cross-sectional shapes of the first portion 31a and the second portion 31b when a cross section is taken in the lateral direction of the first portion 31a and the second portion 31b are not limited, and examples thereof include a polygonal shape such as a square shape or a rectangular shape, a circular shape, and an elliptical shape. Among them, the square shape is preferable in terms of the transmission efficiency of the optical signal.

As illustrated in FIG. 2, the cladding 32 is positioned on the upper and lower surfaces of the core 31. As illustrated in FIGS. 3 and 4, the cladding 32 includes a first cladding 32a and a second cladding 32b. The first cladding 32a is positioned sandwiching the first upper surface 31al and the first lower surface 31a2 of the first portion 31a of the core 31, and the second cladding 32b is positioned sandwiching the second upper surface 31b1 and the second lower surface 31b2 of the second portion 31b of the core 31.

The material forming the first cladding 32a is not limited, and examples thereof include an epoxy resin and a silicone resin. The material forming the second cladding 32b is not limited, and examples thereof include an epoxy resin and a silicone resin. In the optical circuit board 1 according to the embodiment, the refractive index of the second cladding 32b may be greater than the refractive index of the first cladding 32a. The cladding 32 sandwiching the tapered portion 31c is not particularly limited, and may be either the first cladding 32a or the second cladding 32b. For example, a part of the tapered portion 31 may be sandwiched by the first cladding 32a, and the remaining part thereof may be sandwiched by the second cladding 32b.

In the first cladding 32a, the first cladding 31a positioned on the first lower surface 31a2 side of the first portion 32a may have a groove 321 along an end portion of the first portion 31a on the optical component 4 side, as illustrated in FIG. 3. Due to the presence of such a groove 321, when a sealing resin is filled between the optical component 4 and the first cladding 31a positioned on the first lower surface 31a2 side of the first portion 32a, an excess sealing resin accumulates in the groove 321. As a result, the sealing resin is less likely to flow between facing surfaces of the Si waveguide 41 and the first portion 31a, and transmission and reception of the optical signal are less likely to be inhibited.

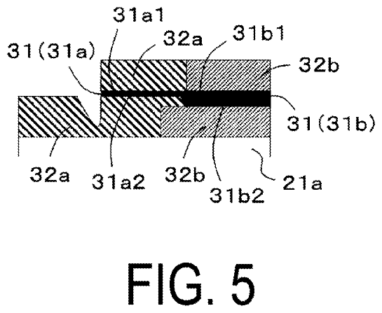

The arrangement of the cladding 32 is not limited as long as the first cladding 32a is positioned sandwiching the first upper surface 31a1 and the first lower surface 31a2 of the first portion 31a of the core 31 and the second cladding 32b is positioned sandwiching the second upper surface 31b1 and the second lower surface 31b2 of the second portion 31b of the core 31, as described above. For example, as illustrated in FIG. 5, a first cladding upper surface of the first cladding 32a positioned on the first upper surface 31a1 side of the first portion 31a may be flush with a second cladding upper surface of the second cladding 32b positioned on the second upper surface 31b1 side of the second portion 31b. With the positional relationship illustrated in FIG. 5, the height of the optical waveguide 3 can be reduced. As a result, the optical circuit board 1 can be further downsized.

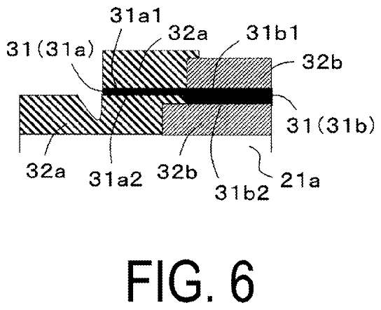

As illustrated in FIG. 6, the first cladding 32a positioned on the first upper surface 31al side of the first portion 31a may cover a part of the second cladding upper surface of the second cladding 32b positioned on the second upper surface 31b1 side of the second portion 31b. With the positional relationship illustrated in FIG. 6, the first cladding 32a positioned on the first upper surface 31a1 side of the first portion 31a presses the second cladding 32b positioned on the second upper surface 31b1 side of the second portion 31b. As a result, peeling and floating of the second cladding 32b can be prevented. By reducing the entry of foreign matter into a clearance between the first cladding 32a and the second cladding 32b, the transmission characteristics of the optical signal can be improved. When the first cladding 32a covers the entire second cladding upper surface of the second cladding 32b, the above-described effect can be easily obtained.

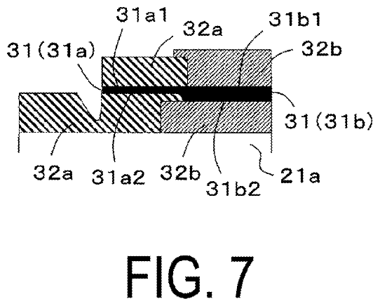

As illustrated in FIG. 7, the second cladding 32b positioned on the second upper surface 31b1 side of the second portion 31b may cover a part of the first cladding upper surface of the first cladding 32a positioned on the first upper surface 31a1 side of the first portion 31a. With the positional relationship illustrated in FIG. 7, the second cladding 32b positioned on the second upper surface 31b 1 side of the second portion side 31b presses the first cladding 32a positioned on the first upper surface 31a1 side of the first portion 31a. As a result, peeling and floating of the first cladding 32a can be prevented. By reducing the entry of foreign matter into a clearance between the first cladding 32a and the second cladding 32b, the transmission characteristics of the optical signal can be improved. When the second cladding 32b covers the entire first cladding upper surface of the first cladding side 32a, the above-described effect can be easily obtained.

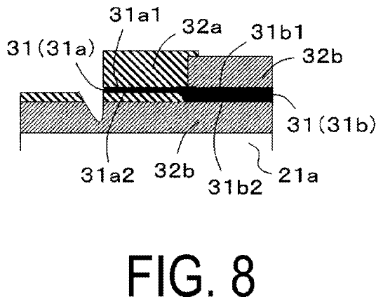

As illustrated in FIG. 8, the second cladding 32b positioned on the second lower surface 31b2 side of the second portion 31b may extend between the first cladding 32a positioned on the first lower surface 31a2 side of the first portion 31a, and the wiring board 2. In the positional relationship illustrated in FIG. 8, in the cladding 32 (lower cladding) positioned on the lower surface side of the core 31, there is no boundary in a direction perpendicular to the extending direction of the core 31. That is, there is no boundary between the first cladding 32a and the second cladding 32b on the lower surface side of the core 31. As a result, the flatness of the optical waveguide 3 is further improved.

In the optical circuit board 1 according to the embodiment, the optical waveguide 3 can be obtained by, for example, the following method. First, a resin that forms the material of the second cladding 32b is disposed on the surface of the first conductor layer 21a positioned on the surface of the wiring board 2. This resin may be disposed by coating, or may be disposed by laminating plate-shaped bodies such as resin films. Subsequently, the material of the second cladding 32b is exposed to light, developed, and then cured to form the second cladding 32b positioned on the second lower surface 31b2 side of the second portion 31b.

Subsequently, a resin that forms the material of the first cladding 32a is disposed covering the surface of the first conductor layer 21a, which has been exposed as a result of the exposure to the light and the development, and the second cladding 32b positioned on the second lower surface 31b2 side of the second portion 31b. This resin may be disposed by coating, or may be disposed by laminating plate-shaped bodies such as resin films. As the material of the first cladding 32a, a resin having a lower refractive index than that of the material of the second cladding 32b is used.

Subsequently, the resin that forms the material of the first cladding 32a is exposed to light, developed, and then cured to form the first cladding 32a positioned on the first lower surface 31a2 side of the first portion 31a. By forming the first cladding 32a covering a part of the second cladding 32b, the thickness of the second portion 31b of the core 31 can be made thicker than the thickness of the first portion 31a of the core 31 in a cross-sectional view. An end surface of the first cladding 32a positioned on the surface of the second cladding 32b may be perpendicular or inclined. By inclining the end surface, the tapered portion 31c can be formed.

A resin that forms the material of the core 31 is disposed covering the first cladding 32a and the second cladding 32b. This resin may be disposed by coating, or may be disposed by laminating plate-shaped bodies such as resin films. The resin that forms the material of the core 31 is exposed to light, developed, and then cured to form the core 31. The core 31 positioned at the first cladding 32a corresponds to the first portion 31a, and the core 31 positioned at the second cladding 32b corresponds to the second portion 31b.

Subsequently, the resin that forms the material of the second cladding 32b is disposed covering the core 31. This resin may be disposed by coating, or may be disposed by laminating plate-shaped bodies such as resin films. Subsequently, the resin that forms the material of the second cladding 32b is exposed to light, developed, and then cured to form the second cladding 32b positioned on the second upper surface side 31b1 side of the second portion 31b.

Subsequently, the resin that forms the material of the first cladding 32a is disposed covering the core 31 and the second cladding 32b positioned on the second upper surface 31b1 side of the second portion 31b. This resin may be disposed by coating, or may be disposed by laminating plate-shaped bodies such as resin films. Subsequently, the resin that forms the material of the first cladding 32a is exposed to light, developed, and then cured to form the first cladding 32a positioned on the first upper surface side 31a1 side of the first portion 31a.

Subsequently, an end surface of the first portion 31a, that is, an end surface of the first portion 31a on the optical component 4 side is formed by, for example, laser processing or the like. The groove 321 may be formed along the end portion of the first portion 31a on the optical component 4 side. The optical waveguide 3 is formed in this manner.

A method of adjusting the core 31 and the numerical aperture (NA) of the optical waveguide 3 is as follows. The numerical aperture (NA) is a value calculated from a difference in the refractive index between the core and the cladding, and is a parameter for determining the MFD.

First, the MFD is specified from the size of the Si waveguide 41 included in the silicon photonics device 4. The MFD of the optical waveguide 3 is determined from the MFD of the Si waveguide 41. Subsequently, based on the MFD of the optical waveguide 3, a range of the NA is determined (e.g., 0.1 or more). Realizable diameters of the core 31 (the diameter of the first portion 31a and the diameter of the second portion 31b) and the NA are determined from the range of the NA. From this NA, necessary differences in the refractive index (a difference between the refractive index of the first portion 31a of the core 31 and the refractive index of the first cladding 32a, and a difference between the refractive index of the second portion 31b of the core 31 and the refractive index of the second cladding 32b) are determined. Based on these differences in the refractive index, the diameter of the first portion 31a, the diameter of the second portion 31b, the material of the first cladding 32a, and the material of the second cladding 32b are determined.

An optical component mounting structure of the present disclosure will be described. In the embodiment of the present disclosure, the optical component mounting structure 10 has a structure in which the silicon photonics device 4 and an electronic component 6 are mounted on the optical circuit board 1 according to the embodiment. Examples of the electronic component 6 include an application specific integrated circuit (ASIC) and a driver IC.

As illustrated in FIG. 2, the silicon photonics device 4 is electrically connected, via a solder 7, to an electrode 21b positioned in the mounting region of the optical component on the wiring board 2. The electrode 21b is a part of the conductor layer positioned on the upper surface of the wiring board 2, and is positioned exposed from an opening of a solder resist 8.

The silicon photonics device 4 is one type of optical waveguide having, for example, a core made of silicon (Si) and a cladding made of silicon dioxide (SiO₂). The silicon photonics device 4 includes the Si waveguide 41 as described above and further includes a passivation film, a light source, and a photodetector (not illustrated). As described in FIGS. 3 and 4, the Si waveguide 41 is positioned facing the first portion 31a of the core 31 included in the optical waveguide 3, at one end portion of the optical waveguide 3.

For example, an electrical signal from the wiring board 2 propagates to the light source included in the silicon photonics device 4 via the solder 7. The light source emits light upon receiving the propagated electrical signal. The optical signal of this emitted light propagates to an optical fiber 5, connected via an optical connector 5a, through the Si waveguide 41 for signal propagation and the core 31 of the optical waveguide 3.

The optical circuit board according to the present disclosure is not limited to the optical circuit board 1 according to the embodiment described above. In the optical circuit board 1 according to the above-described embodiment, the groove 321 is provided in the first cladding 32a positioned on the lower surface side of the first portion 31a of the core 31. However, in the optical circuit board according to the present disclosure, the groove is not an essential constituent element, and may be provided as necessary.

In the optical circuit board 1 according to the above-described embodiment, the tapered portion 31c is present between the first portion 31a of the core 31 and the second portion 31b of the core 31. However, in the optical circuit board according to the present disclosure, the tapered portion 31c need not necessarily be present, and the first portion 31a and the second portion 31b may be directly connected to each other.

### REFERENCE SIGNS

1 Optical circuit board
2 Wiring board
21a First conductor layer
21b Electrode
23 Insulating layer
3 Optical waveguide
31 Core
31a First portion
31a1 First upper surface
31a2 First lower surface
31b Second portion
31b1 Second upper surface
31b2 Second lower surface
31c Tapered portion
32 Cladding
32a First cladding
32b Second cladding
321 Groove
4 Silicon photonics device (optical component)
41 Silicon waveguide (Si waveguide)
5 Optical fiber
5a Optical connector
6 Electronic component
7 Solder
8 Solder resist
10 Optical component mounting structure

1. An optical circuit board comprising:
a wiring board comprising an upper surface; and
an optical waveguide, wherein
a part of the upper surface of the wiring board is a mounting region of an optical component,
the optical waveguide is positioned adjacent to the mounting region of the optical component on the wiring board and comprises a core, a first cladding, and a second cladding,
the core comprises a first portion having a first upper surface and a first lower surface and a second portion having a second upper surface and a second lower surface,
the first cladding is positioned sandwiching the first upper surface and the first lower surface of the first portion of the core,
the second cladding is positioned sandwiching the second upper surface and the second lower surface of the second portion of the core,
a width of the second portion is greater than a width of the first portion,
a thickness of the second portion is greater than a thickness of the first portion, and
a refractive index of the second cladding is greater than a refractive index of the first cladding.

2. The optical circuit board according to claim 1, wherein the core comprises a tapered portion between the first portion and the second portion, a width and a thickness of the tapered portion decreasing from an end portion of the second portion toward an end portion of the first portion.

3. The optical circuit board according to claim 1, wherein the first cladding positioned on the first lower surface side of the first portion comprises a groove along an end portion of the first portion on the optical component side.

4. The optical circuit board according to claim 1, wherein a first cladding upper surface of the first cladding positioned on the first upper surface side of the first portion is flush with a second cladding upper surface of the second cladding positioned on the second upper surface side of the second portion.

5. The optical circuit board according to claim 1, wherein the first cladding positioned on the first upper surface side of the first portion covers a part of the second cladding upper surface of the second cladding positioned on the second upper surface side of the second portion.

6. The optical circuit board according to claim 1, wherein the second cladding positioned on the second upper surface side of the second portion covers a part of the first cladding upper surface of the first cladding positioned on the first upper surface side of the first portion.

7. The optical circuit board according to claim 1, wherein the second cladding positioned on the second lower surface side of the second portion extends between the wiring board and the first cladding positioned on the first lower surface side of the first portion.

8. The optical circuit board according to claim 1, wherein
the first upper surface of the first portion is flush with the second upper surface of the second portion, and
a center of the width of the first portion and a center of the width of the second portion coincide with each other in a plan view.

9. The optical circuit board according to claim 1, wherein a central axis of the first portion and a central axis of the second portion are on the same axis with each other.

10. The optical circuit board according to claim 1, wherein a cross section of the first portion and a cross section of the second portion each have a square shape.

11. The optical circuit board according to claim 1, wherein a conductor is positioned between the wiring board and the optical waveguide.

12. An optical component mounting structure comprising:
the optical circuit board according to claim 1; and
an optical component mounted in the mounting region.

13. The optical component mounting structure according to claim 12, wherein
the optical component is a silicon photonics device,
the silicon photonics device comprises a silicon waveguide, and
the silicon waveguide is positioned facing the first portion of the core.
